(19) United States
(12) Patent Application Publication
(10) Pub. No.: US 2015/0012904 A1
(43) Pub. Date: Jan. 8, 2015

(54) SYSTEM AND METHOD FOR SETTING ELECTRICAL SPECIFICATION OF SIGNAL TRANSMISSION LINE

(71) Applicant: HON HAI PRECISION INDUSTRY CO., LTD., New Taipei (TW)

(72) Inventors: CHENG-HSIEN LEE, New Taipei (TW); SHIN-TING YEN, New Taipei (TW)

(73) Assignee: HON HAI PRECISION INDUSTRY CO., LTD., New Taipei (TW)

(21) Appl. No.: 14/086,973

(22) Filed: Nov. 22, 2013

(30) Foreign Application Priority Data
Jul. 4, 2013 (TW) 102124083

(51) Int. Cl. H05K 3/00

(52) U.S. Cl. CPC H05K 3/0005
USPC 716/137

(57) ABSTRACT

A computer-based method for setting electrical specification of signal transmission lines of a printed circuit board (PCB) layout is provided. Data recorded in an electrical specification file is imported. The electrical specification file records a number of chips, pins of each chip, and electrical specification corresponding to each chip. The PCB layout is searched to find the chips and the pins recorded in the electrical specification file. The electrical specification of signal transmission lines connected to the found pins is set according to the electrical specification corresponding to each chip.

### BACKGROUND

1. Technical Field

Embodiments of the present disclosure relates to circuit simulating systems and methods, and more particularly, to a system and a method for setting electrical specification of signal transmission lines of a printed circuit board (PCB) layout.

2. Description of Related Art

Electrical specification of signal transmission lines should be set in a printed circuit board (PCB) layout. However, setting the electrical specification of signal transmission lines is often done manually, which is not only time-consuming, but also error-prone.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a block diagram of one embodiment of a computing device for setting electrical specification of signal transmission lines of a PCB layout.

FIG. 2 is a block diagram of one embodiment of function modules of a setting system of the computing device of FIG. 1.

FIG. 3 is a flowchart of one embodiment of a method for setting electrical specification of signal transmission lines of a PCB layout.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean at least one.

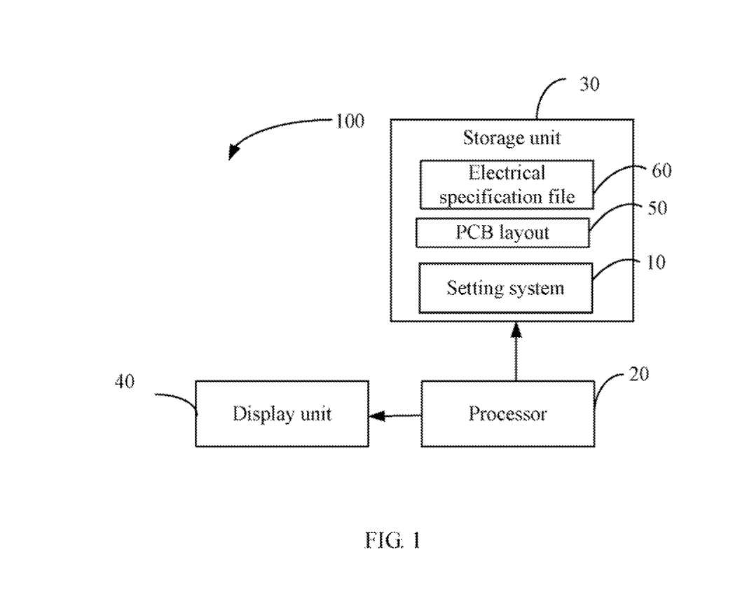

FIG. 1 is a block diagram of one embodiment of a computing device 10. The computing device 10 includes a processor 20, a storage unit 30, and a display unit 40. The storage unit 30 may be a smart media card, a secure digital card, or a flash card. The storage unit 30 stores computerized codes of a setting system 10, at least one PCB layout 50, and an electrical specification file 60. The file 60 contains a number of chips, pins of each chip, and electrical specification corresponding to each chip. The setting system 10 includes various software components and/or a set of instructions, which may be implemented by the processor 20 to search the PCB layout 50 to find the chips and the pins recorded in the file 60, and set electrical specification of signal transmission lines connected to the found pins chips according to the electrical specification corresponding to each chip.

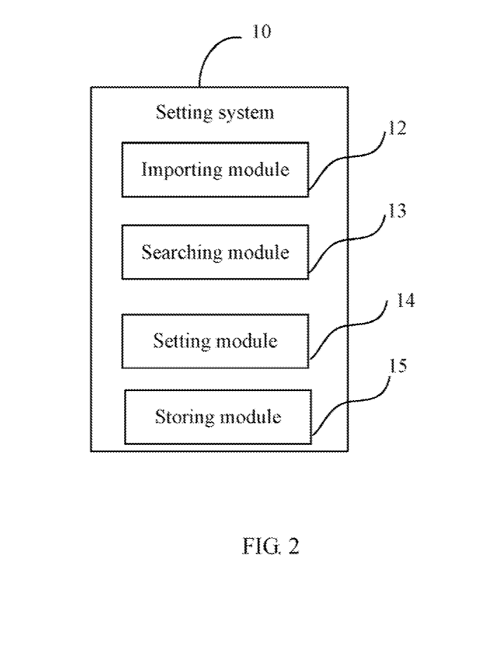

FIG. 2 is a block diagram of the function modules of the setting system 10 in the computing device 100 of FIG. 1. In one embodiment, the setting system 10 includes an importing module 12, a searching module 13, a setting module 14, and a storing module 15.

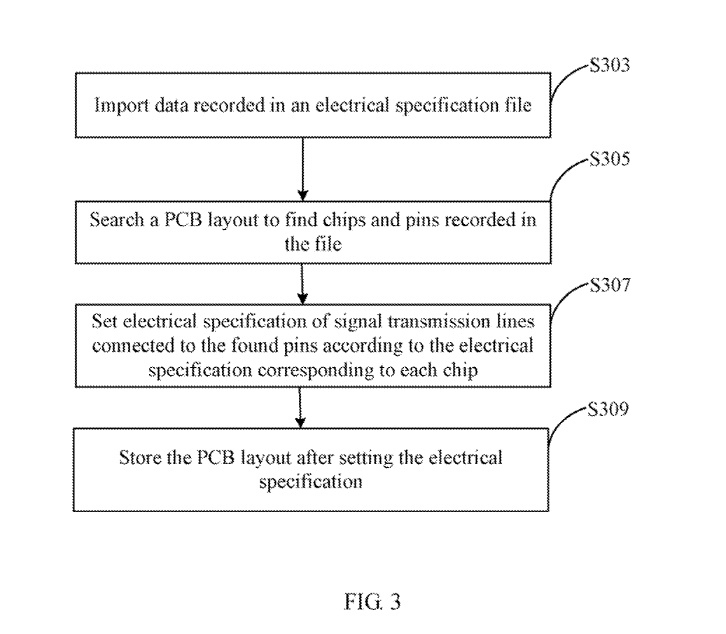

FIG. 3 is a flowchart of a method for setting the electrical specification of signal transmission lines, in accordance with an exemplary embodiment.

In step S303, the importing module 12 imports data recorded in the file 60.

In step S305, the searching module 13 searches the PCB layout 50 to find the chips and the pins recorded in the file 60.

In step S307, the setting module 14 sets the electrical specification of signal transmission lines connected to the found pins according to the electrical specification corresponding to each chip.

In step S309, the storing module 15 stores the PCB layout 50 after setting the electrical specification.

Although certain embodiments of the present disclosure have been specifically described, the present disclosure is not to be construed as being limited thereto. Various changes or modifications may be made to the present disclosure without departing from the scope and spirit of the present disclosure.

1. A computer-based method for setting electrical specification of signal transmission lines of a printed circuit board (PCB) layout, the method comprising:
importing data recorded in an electrical specification file by a processor of a computing device, the electrical specification file being stored in an storage unit of the computing device and containing a plurality of chips, pins of each of the plurality of chips, and electrical specification corresponding to each of the plurality of chips, the electrical specification comprising an amount, a length and a width of signal transmission lines connected to each pin of the chips;
searching the PCB layout to find the chips and the pins recorded in the electrical specification file by the processor; and
setting the amount, the length, and the width of signal transmission lines connected to the found pins automatically by the processor according to the electrical specification corresponding to each of the plurality of chips.

2. The method as claimed in claim 1, further comprising:
storing the PCB layout to a storage device by the processor after setting the electrical specification of signal transmission lines connected to the found pins.

3. A system for setting electrical specification of signal transmission lines of a printed circuit board (PCB) layout, the system comprising:
one or more computing devices; and
one or more computer-readable media coupled to the one or more computing devices and having instructions stored thereon which, when executed by the one or more computing devices, cause the one or more computing devices to perform operations for setting electrical specification of signal transmission lines, the operations comprising:
importing data recorded in an electrical specification file stored in an storage unit, the electrical specification file containing a plurality of chips, pins of each of the plurality of chips, and electrical specification corresponding to each of the plurality of chips, the electrical specification comprising an amount of signal transmission lines connected to each pin of the chips, a length and a width of the signal transmission lines connected to each pin of the chips;
searching the PCB layout to find the chips and the pins recorded in the electrical specification file; and
setting the amount, the length, and the width of signal transmission lines connected to the found pins according to the electrical specification corresponding to each of the plurality of chips.

4. The system as described in claim 3, wherein the operations further comprising:
storing the PCB layout after setting the electrical specification of signal transmission lines connected to the found pins.

5. A non-transitory computer storage medium encoded with a computer program, the program comprising instructions that when executed by one or more computers cause the one or more computers to perform operations comprising:
importing data recorded in an electrical specification file stored in a storage unit, the electrical specification file containing a plurality of chips, pins of each of the plurality of chips, and electrical specification corresponding to each of the plurality of chips, the electrical specification comprising an amount of signal transmission lines connected to each pin of the chips, a length and a width of the signal transmission lines connected to each pin of the chips;
searching a printed circuit board (PCB) layout to find the chips and the pins recorded in the electrical specification file; and
setting the amount, the length, and the width of signal transmission lines connected to the found pins according to the electrical specification corresponding to each of the plurality of chips.

6. The non-transitory computer storage medium as described in claim 5, wherein the operations further comprising:
storing the PCB layout after setting the electrical specification of signal transmission lines connected to the found pins.
